(19) United States
(12) Patent Application Publication
(10) Pub. No.: US 2026/0364623 A1
(43) Pub. Date: Nov. 19, 2026

(54) SHOWERHEAD AND NOZZLE STRUCTURE, AND METHOD OF CONTROLLING AND CALIBRATING SHOWERHEAD AND NOZZLE STRUCTURE

(71) Applicant: Taiwan Semiconductor Manufacturing Co., Ltd., Hsinchu (TW)

(72) Inventors: Ming Lun YOU, Hsinchu (TW); Fan Hsuan CHIEN, Hsinchu (TW); Pei Yen CHENG, Hsinchu (TW); Yi-Wen CHEN, Hsinchu (TW); Kai-Shiung HSU, Hsinchu (TW); Yu-Kun HUANG, Hsinchu (TW)

(73) Assignee: Taiwan Semiconductor Manufacturing Co., Ltd., Hsinchu (TW)

(21) Appl. No.: 19/755,299

(22) Filed: Jul. 27, 2026

Related U.S. Application Data
(63) Continuation of application No. 18/821,646, filed on Aug. 30, 2024.

(51) Int. Cl. B05B 12/00

(52) U.S. Cl. CPC B05B 12/008

(57) ABSTRACT

A method of pre-testing, calibrating, or testing a showerhead before being installed within a workpiece processing tool or already installed within a workpiece processing tool. By pre-testing or calibrating the showerhead in advance of being installed into a workpiece processing tool, the evenness and levelness of one or more layers to be formed on a surface of a workpiece is optimized and the downtime of the workpiece processing tool is reduced increasing a yield number of devices output by the semiconductor manufacturing plant. The showerhead includes one or more nozzle structures that are removable from the showerhead such that the position and type of nozzle structures may be removed or adjusted in position to calibrate the showerhead in advance of being installed within the workpiece processing tool or while the showerhead is installed in the workpiece processing tool.

### PRIORITY CLAIM

This application is a continuation of U.S. patent application Ser. No. 18/821,646, filed on Aug. 30, 2024, which is incorporated by reference herein in its entirety.

### BACKGROUND

In manufacturing or producing devices such as semiconductor die, packages, or some other similar or like type of semiconductor device, layers of materials are formed on a surface of a workpiece (e.g., a substrate, a wafer, or some other similar or like type of workpiece). To deposit these layers of material, which may be thin films or layers, onto the surface of the workpiece, a semiconductor manufacturing tool is utilized. To prevent or reduce the likelihood of defects within the manufactured product, the layers of material are manufactured within selected tolerances such that there is a low likelihood or no likelihood of defects being present within the manufactured semiconductor device. For example, when these layers of material are formed outside the selected tolerances the likelihood of defects propagating during the manufacturing process of the semiconductor device or product is increased as well. As electronic devices and semiconductor devices become smaller in profile (e.g., smaller in overall size and thinner in overall thickness), forming the layers of material within the selected tolerances becomes ever increasingly difficult. To increase the likelihood of forming the layers of material within the selected tolerances, the tool utilized to form the layers of material is calibrated to increase the likelihood of forming the layers of material within the selected tolerances.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a top view of a process chamber of a workpiece processing tool including an exhaust structure.

FIG. 1B is a top view of a heat map of a layer formed on a workpiece within the process chamber of the workpiece processing tool including the exhaust structure as shown in FIG. 1A.

FIG. 1C is a top view of a heat map of air extraction from the process chamber through the exhaust structure of the workpiece processing tool as shown in FIG. 1A that is utilized to form the layer on the workpiece as shown in FIG. 1B.

FIG. 2A is a side view of an assembly utilized within a workpiece processing tool to form a layer on a workpiece, in accordance with some embodiments.

FIG. 2B is a perspective view of the assembly utilized within the workpiece processing tool to form the layer on the workpiece, in accordance with some embodiments.

FIG. 3A is a perspective view of a showerhead, in accordance with some embodiments.

FIG. 3B is a bottom view of the showerhead as shown in FIG. 3A, in accordance with some embodiments.

FIG. 3C is a cross-sectional, zoomed in, and enhanced view of a nozzle structure of the showerhead as shown in FIGS. 3A and 3B, in accordance with some embodiments.

FIG. 3D is a top view of the showerhead as shown in FIGS. 3A-3C with some features hidden for ease of understanding, in accordance with some embodiments.

FIG. 4A is a top view of an alternative showerhead, in accordance with some embodiments.

FIG. 4B is a cross-sectional zoomed in, enhanced view of an alternative nozzle of the alternative showerhead as shown in FIG. 4A, in accordance with some embodiments.

FIG. 4C is a schematic diagram of a Wheatstone bridge circuit of the alternative nozzle structure as shown in FIG. 4B of the alternative showerhead as shown in FIG. 4A, in accordance with some embodiments.

FIG. 5 is a diagram of a system for pre-testing or testing a showerhead, in accordance with some embodiments.

FIG. 6 is a flowchart for utilizing the system as shown in FIG. 5 for performing a method of pre-testing, calibrating, or testing the showerhead, in accordance with some embodiments.

FIG. 7 is a diagram of the system as shown in FIG. 5 for pre-testing or testing a showerhead installed within a workpiece processing tool, in accordance with some embodiments.

FIG. 8 is a flowchart for utilizing the system as shown in FIG. 7 for performing a method of pre-testing or testing the showerhead, in accordance with some embodiments.

FIG. 9A is a perspective view of a robotic arm for pre-testing, calibrating, or testing a showerhead, in accordance with some embodiments.

FIG. 9B is a side view of the robotic arm system as shown in FIG. 9B for pre-testing or testing the showerhead, in accordance with some embodiments.

FIG. 9C is a bottom view of an end effector of the robotic arm for pre-testing or testing the showerhead, in accordance with some embodiments.

FIG. 10 is a side view of a workpiece processing tool including a showerhead, in accordance with some embodiments.

FIG. 11 is a flowchart for utilizing the workpiece processing tool including the showerhead as shown in FIG. 10 for performing a method of forming one or more layers on a workpiece, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

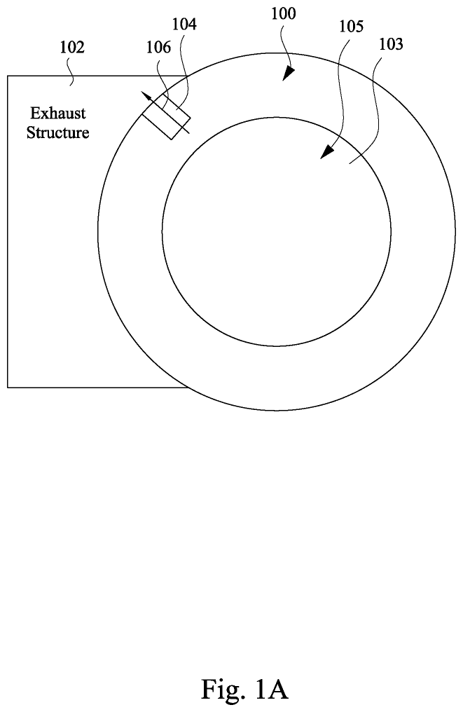

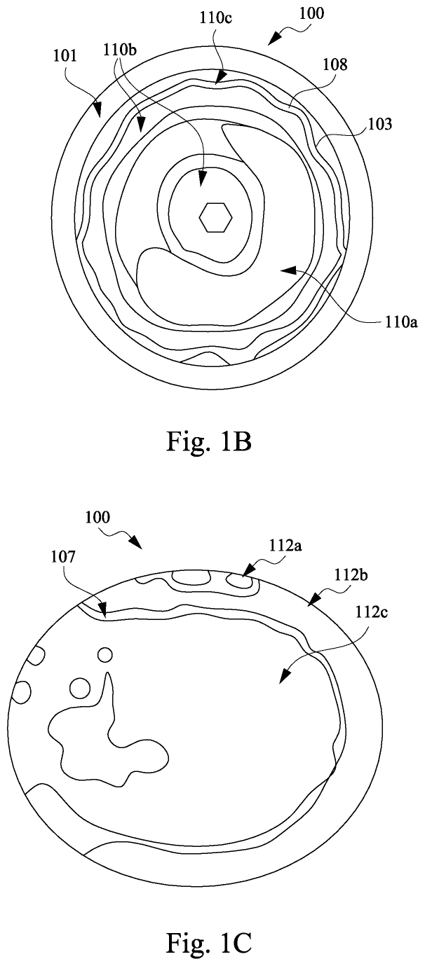

FIG. 1A is a top view of a process chamber 100 of a workpiece processing tool including an exhaust structure 102. The process chamber 100 is configured to, in operation, contain a workpiece (e.g., a silicon wafer) 103 such that one or more layers are formed on a surface 105 of the workpiece 103. The exhaust structure 102 is in fluid communication with the process chamber 100 through an exhaust opening structure 104 that extends into the process chamber 100. It will be readily appreciated that the exhaust opening structure 104 is shown in a simplified form. The exhaust opening structure 104 extending into the process chamber 100 and allowing for a fluid (e.g., a material in a gaseous state, a liquid state, or some combination of gaseous or liquid states) to exit the process chamber 100 effects a flow pattern of the fluid throughout the entirety of the process chamber 100. In other words, a position of the exhaust opening structure 104 effects the flow pattern of the fluid throughout the process chamber 100. The flow of the fluid out of the process chamber 100 and into the exhaust structure 102 through the exhaust opening structure 104 is represented by an arrow 106.

While not shown in FIG. 1A, a showerhead with a plurality of nozzles is utilized to introduce the fluid into the process chamber 100. As the exhaust opening structure 104 extends into the process chamber 100 effecting the flow pattern of the fluid throughout the process chamber 100, overtime condensate builds up on and within the plurality of nozzles due to the exhaust opening structure 104 effecting the flow pattern of the fluid within the process chamber 100. In other words, the flow pattern within the process chamber 100 is unoptimized due to the presence of the exhaust opening structure 104 being present within the process chamber 100. The unoptimized flow pattern within the process chamber 100 results in one or more uneven or unlevel layers being formed on the workpiece 103 within the process chamber 100. These uneven or unlevel layers increase the likelihood of manufacturing semiconductor products or devices outside selected tolerances resulting in increased waste cost of the FAB.

FIG. 1B is a top view of a heat map 101 of one or more layers 108 formed on the surface 105 of the workpiece 103 within the process chamber 100 of the workpiece processing tool as shown in FIG. 1A. As shown in the heat map, there is one or more high regions 110a, one or more intermediate regions 110b, and one or more low regions 110c. The one or more high regions 110a are regions at which the one or more layers 108 are formed thicker relative to the one or more intermediate regions 110b and the one or more low regions 110c. The one or more intermediate regions 110b are regions at which the one or more layers 108 is formed less thick than the one or more layers 108 at the one or more high regions 110a, and the one or more intermediate regions 110b are regions at which the one or more layers 108 is formed thicker than the one or more layers 108 at the one or more low regions 110c. The one or more low regions 110c are regions at which the one or more layers 108 are formed less thick relative to the one or more high regions 110a and the one or more intermediate regions 110b.

A first one of the one or more intermediate regions 110b of the one or more layers 108 is present at a center of workpiece 103 and a second one of the one or more intermediate regions 110b of the one or more layers 108 is present in close proximity to an edge of the workpiece 103. At least one high region 110a of the one or more high regions 110a of the one or more layers 108 is between the first and second one of the one or more intermediate regions 110b of the one or more layers 108. At least one low region 110c of the one or more low regions 110c of the one or more layers 108 is at the edge of the workpiece 103. In view of these one or more high regions 110a, the one or more intermediate regions 110b, and the one or more low regions 110c, the one or more layers 108 are formed relative uneven and unlevel when utilizing the process chamber 100 in which the exhaust opening structure 104 is present.

FIG. 1C is a top view of a heat map 107 of air extraction from the process chamber 100 through the exhaust opening structure 104 and into the exhaust structure 102 of the workpiece processing tool as shown in FIG. 1A that is utilized to form the one or more layers 108 on the surface 105 of the workpiece 103. The workpiece 103 is hidden in FIG. 1C such that the entirety of the process chamber 100 is visible in FIG. 1C. The heat map 107 of air extraction from the process chamber 100 through the exhaust opening structure 104 includes at least one high flow region 112a, at least one intermediate flow region 112b, and at least one low flow region 112c.

A high flow rate at the at least one high flow region 112a is greater than an intermediate flow rate at the at least one intermediate flow region 112b and is greater than a low flow rate at the at least one low flow region 112c. The intermediate flow rate at the at least one intermediate flow region 112b is less than the high flow rate at the at least one high flow region 112a and is greater than the low flow rate at the at least one low flow region 112c. The low flow rate at the at least one low flow region 112c is less than the high flow rate at the at least one high flow region 112a and is less than the intermediate flow rate at the at least one intermediate flow rate region 112b. These variations in the flow rate are caused by the plurality of nozzles of the showerhead being unoptimized, as well as the exhaust opening structure 104 being present within the process chamber. These variations in the respective flow rate at the at least one high flow region 112a, the at least one intermediate flow region 112b, and the at least one low flow region 112c cause the variations in the thicknesses of the layer 108 formed at the one or more high regions 110a, the one or more intermediate regions 110b, and the one or more low regions 110c.

In view of the above discussion of FIGS. 1A-1C, when manufacturing semiconductor products or devices within a semiconductor manufacturing plant (FAB), one or more layers of materials are formed on a workpiece (e.g., a silicon wafer) within a process chamber. As the semiconductor products or devices become more and more complex, tolerances in forming the one or more layers of materials on the workpiece become ever increasingly strict to reduce the likelihood or prevent manufacturing or producing semiconductor products or devices that function outside of selected tolerances. For example, by improving a levelness or evenness of the one or more layers as they are formed on the workpiece, this reduces the likelihood or prevents manufacturing or producing the semiconductor products or devices being manufactured that are not functioning within the selected tolerances. The one or more layers are formed on the workpiece processing tool by utilizing a showerhead. The evenness and levelness of the one or more layers is effected by an exhaust structure within a process chamber (see discussion with respect to FIGS. 1A-1C earlier herein). The exhaust structure limits a flow of a fluid (e.g., a gaseous state material, a liquid state material, or some combination of gaseous state and liquid state material) through the process chamber causing the one or more layers being formed to be uneven or unlevel (see discussion with respect to FIGS. 1A-1C earlier herein).

In view of the above discussion of FIGS. 1A-1C, the present disclosure is directed to structures and methods that are utilized to pre-test a showerhead, as well as structures to monitor a flow of a fluid through a showerhead relative to a database containing pre-layer information to improve the evenness and levelness of the one or more layers formed on the workpiece utilizing the showerhead. The showerhead is pre-tested to optimize the showerhead by comparing the flow through one or more nozzles of the showerhead to a database containing the pre-layer information. During this pre-testing process, the position of the one or more nozzles, which are removable from the showerhead, are repositioned to optimize a flow pattern output through the one or more nozzles of the showerhead to take into consideration an exhaust structure within a process chamber. By optimizing the position of the one or more nozzles of the showerhead based on the pre-layer information, the evenness and levelness of the one or more layers that are manufactured by utilizing the showerhead is improved. Improving the evenness and levelness of the one or more layers reduces or prevents the likelihood of manufacturing out of tolerance semiconductor packages or devices.

In view of the above discussion with respect to FIGS. 1A-1C, by monitoring the flowrates through the one or more nozzles of the showerhead in real time, the quality and consistency of the flowrate through the one or more nozzles can be monitored and compared to the pre-layer information in the database in real time such that when the showerhead is not functioning within a desired tolerance, the showerhead can be cleaned or tunned. For example, when it is determined that a respective nozzle of the one or more nozzles is not providing a desired flowrate based on the pre-layer information within the database, the respective nozzle is replaced or cleaned to re-optimize the flow pattern through the process chamber in which an exhaust opening structure is present.

To summarize the discussion above, the present disclosure is directed to improving the evenness and levelness of these one or more layers that are formed on the workpiece to prevent the issues as discussed earlier herein with respect to FIGS. 1A-1C by pre-testing a showerhead, by monitoring the flowrate through one or more nozzles of a showerhead, or by both pre-testing a showerhead and monitoring a showerhead when in use. The details of improving the evenness and levelness of one or more layers formed on a workpiece will become readily apparent in view of the further discussion that follows herein within the present disclosure.

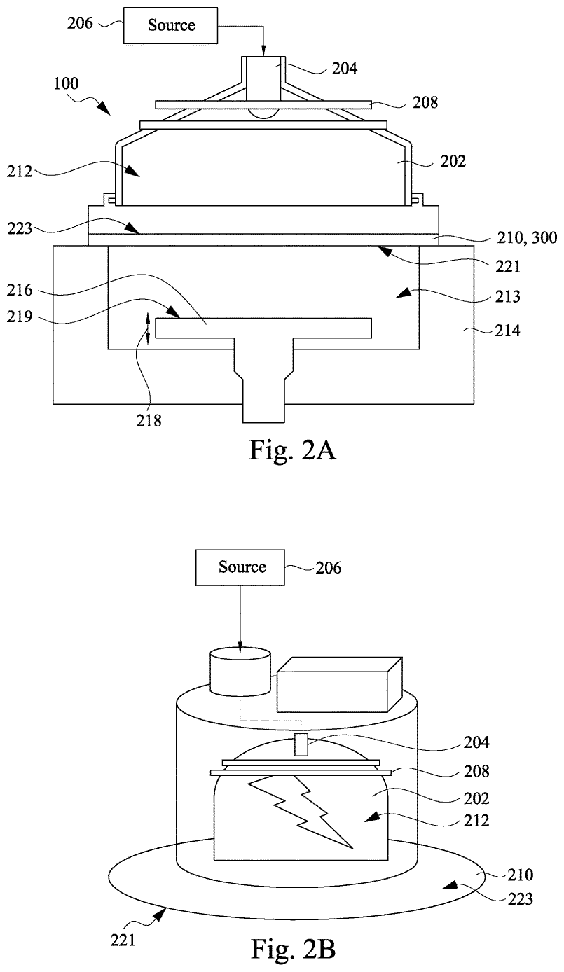

FIG. 2A is a side view of an assembly 200 utilized within a workpiece processing tool to form a layer on a workpiece, in accordance with some embodiments. FIG. 2B is a perspective view of the assembly 200 as shown in FIG. 2A, in accordance with some embodiments. The assembly 200 includes a dome 202 including an inlet structure 204 that is in fluid communication with a source 206. In operation, the source 206 provides a fluid (e.g., a material in a gaseous state, a material in a liquid state, or a material in some combination of a gaseous state and a liquid state) to the dome 202. The material provided by the source 206 may be at least one of the following of Hydrogen (H₂), Helium (He), Oxygen (O₂), or some other suitable material within the semiconductor manufacturing industry that can be provided to the dome 202.

A coil 208 extends along the dome 202. The coil 208 is configured to, in operation, be energized to convert the material introduced into the dome 202 from the source 206 through the inlet structure 204 into a plasma state. The coil 208 is in close proximity to the inlet structure 204 and is in close proximity to an upper end of the dome 202 than a lower end of the dome 202.

A showerhead 210 is at a lower end of the dome 202 and is in fluid communication with a cavity 212 of the dome 202. The showerhead 210 includes a head body 211. The material introduced by the source 206 into the dome 202 through the inlet structure 204 is converted to the plasma state within the cavity 212 of the dome 202. The showerhead 210 is configured to, in operation, eject the material in the plasma state into a process chamber 213 that is delimited by the showerhead 210 and a process chamber housing 214.

A pedestal 216 is present within the process chamber 213. The pedestal 216 is configured to, in operation, move upwards and downwards as represented by an arrow 218. The pedestal 216 includes a workpiece surface 219 on which a respective workpiece is placed when being inserted into the process chamber to form a respective layer on a respective surface of the respective workpiece. The position of the pedestal 216 is configured to, in operation, be moved upward and downward to move the pedestal 216 towards and away from the showerhead 210.

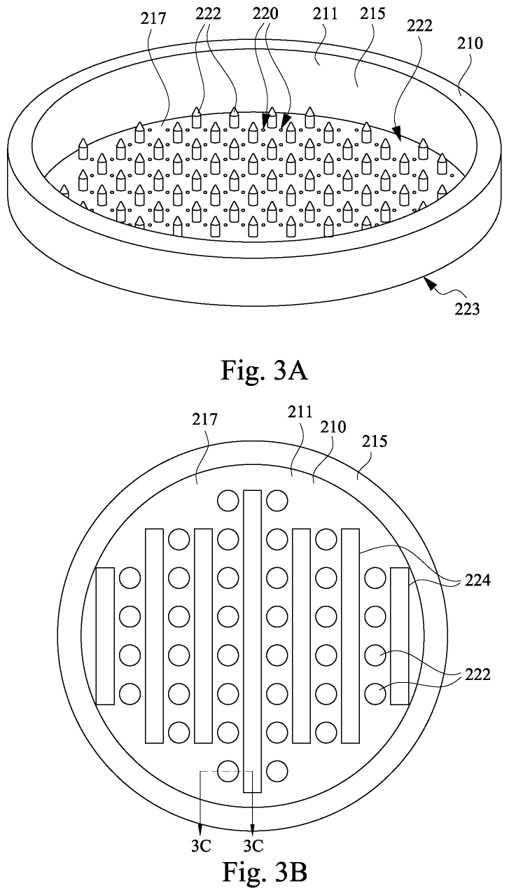

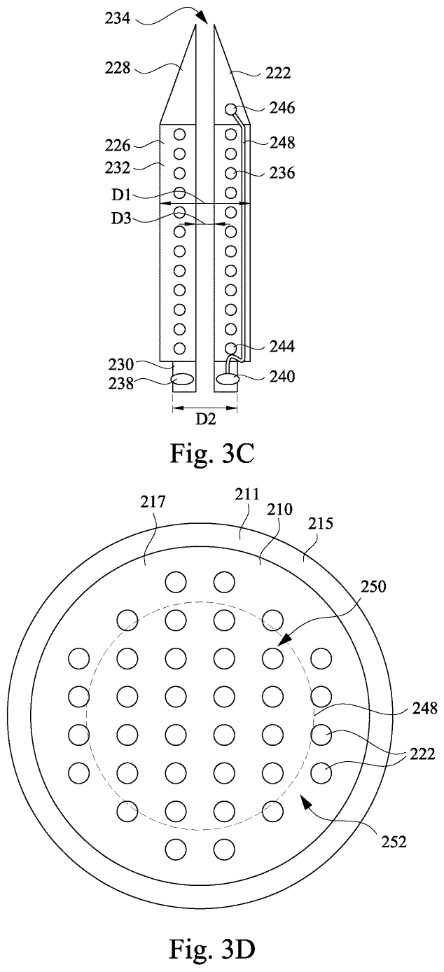

FIG. 3A is a perspective view of the showerhead 210, in accordance with some embodiments. The showerhead 210 includes a peripheral portion 215 of the head body 211 and a central portion 217 of the head body 211 that is surrounded by the peripheral portion 215.

The central portion 217 includes one or more fluid openings 220. The one or more fluid openings 220 extend into the central portion 217. The one or more fluid openings 220 extend into a first surface 221 of the showerhead 210. A second surface 223 of the showerhead 210 is opposite to the first surface 221 of the showerhead 210.

When the showerhead 210 is positioned as shown in FIGS. 2A and 2B, the one or more fluid openings 220 are in fluid communication with the cavity 212 of the dome 202. The one or more fluid openings 220 are structured to receive one or more nozzle structures 222. The one or more fluid openings 220 may remain closed such that the fluid may not readily pass through the one or more fluid openings 220 until a respective nozzle structure of the one or more nozzle structures 222 is coupled to, mounted to, or inserted into a corresponding fluid opening 220 of the one or more fluid openings 220. In other words, if no respective nozzle structure 222 is not coupled to, mounted to, or inserted into a respective fluid opening 220, fluid may not readily pass through the respective fluid opening 220 such that only fluid passes through the respective fluid opening 220 once the respective nozzle structure 222 has been coupled to, mounted to, or inserted into the respective fluid opening 220.

The one or more nozzle structures 222 are removable from the showerhead 210 such that the pattern and position of the one or more nozzle structures 222 is adjustable. The one or more nozzle structures 222 may include nozzle structures with various sized orifices such that some nozzles of the one or more nozzle structures 222 have larger orifices and other nozzles of the nozzle structures 222 have smaller orifices. The one or more nozzle structures 222 may include nozzle structures with various sizes such that some nozzles of the one or more nozzle structures 222 are larger or smaller than other nozzles of the one or more nozzle structures 222. The one or more nozzle structures 222 have various sizes and sized orifices such that a flow pattern within the process chamber 213 is optimized to form and deposit one or more layers that are more even and level than those as discussed earlier herein with respect to FIGS. 1A-1C of the present disclosure.

FIG. 3B is a bottom view of the showerhead 210 as shown in FIG. 3A, in accordance with some embodiments. As shown in FIG. 3B, one or more electromagnetic strips 224 are along regions of the showerhead 210 that are between respective groups of the one or more nozzle structures 222. In some embodiments, the plurality of electromagnetic strips 224 are embedded within the showerhead 210 below the first surface 221 such that the one or more electromagnetic strips 224 are within the showerhead 210 and are between the first surface 221 and the second surface 223. The one or more electromagnetic strips 224 are configured to, in operation, be energized to generate a magnetic field that is utilized to measure a flow rate of a fluid passing through each respective nozzle structure of the plurality of nozzle structures 222.

As shown in the embodiment of the showerhead in FIG. 3B, the one or more nozzle structures 222 are defined into six respective groups that are defined by pairs of the one or more electromagnetic strips 224. As shown in the embodiment of the showerhead in FIG. 3B, the one or more electromagnetic strips 224 includes seven total. While there are six groups of the one or more nozzle structures 222 and there are seven of the one or more electromagnetic strips 224 in this embodiment of the showerhead 210 as shown in FIG. 3B, in some alternative embodiments of the showerhead 210, the alternative embodiments of the showerhead 210 may include different numbers of the groups of the one or more nozzle structures 222 and a different total number of the one or more electromagnetic strips 224.

FIG. 3C is a cross-sectional, zoomed in, and enhanced view along line 3C-3C as shown in FIG. 3B of a respective nozzle structure of the one or more nozzle structures 222 of the showerhead 210 as shown in FIGS. 3A and 3B, in accordance with some embodiments. The respective nozzle structure 222 as shown in FIG. 3C includes a nozzle body 226. A first end portion 228 of the nozzle body 226 is an ejection end portion of the nozzle body 226 of the nozzle structure 222, a second end portion 230 of the nozzle body 226 opposite to the first end portion 228 is an inlet end portion of the nozzle body 226, and an intermediate portion 232 extends from the first end portion 228 to the second end portion 230. The first end 228 is tapered. The intermediate portion 232 has a first dimension D1 that extends across the intermediate portion 232, and the second end portion 230 has a second dimension D2 that extends across the second end portion 230. The first dimension D1 is larger than the second dimension D2. While not shown, in some embodiments, of the showerhead 210, the fluid openings 220 have the second dimension D2 such that, when the second end 230 of the respective nozzle structure 222 is inserted into the corresponding fluid opening 220, the nozzle structure 222 is held in place due to an interference fit between the second end 230 of the respective nozzle structure 222 and the corresponding fluid opening 220.

An orifice or through hole 234 extends entirely through the nozzle body 226 from the first end 228 to the second end 230. The orifice 234 has a third dimension D3 that is less than the first dimension D1 and the second dimension D2. The orifice 234 is an ejection orifice through which a fluid passes through the nozzle body 226. For example, the fluid enters the orifice 234 at the second end portion 230 of the nozzle body 226, passes through the orifice 234 extending through the intermediate portion 232, and is ejected from the first end portion 228 of the nozzle body 226.

A wire 236 is within the nozzle body 226 of the nozzle structure 222. The wire 236 extends from a first wire end 238 to a second wire end 240. The wire 236 includes a coiled portion 242 that has a lower end 244 coupled to the first wire end 238. The coiled portion 242 wraps around and circulates the orifice multiple times such that the coiled portion 242 is coiled around the orifice 234. An upper end 246 of the coiled portion 242 is at the first end 228 of the nozzle body 226 of the nozzle structure 222. An uncoiled portion 249 is coupled to the upper end 246 of the coiled portion 242 and the uncoiled portion 249 extends through the nozzle body 226 to the second wire end 240 of the wire such that the uncoiled portion 249 couples the upper end 246 of the coiled portion 242 to the second wire end 240 of the wire 236.

In operation, when a fluid is passing through the orifice 234 of the nozzle body 226, the wire 236 and the electromagnetic strips 224 are utilized to generate a magnetic field and changes in the magnetic field are monitored such that a respective flow rate through each of the one or more nozzle structures 222 coupled to the showerhead 210 is monitored in real time. For example, the flow rate may be determined by utilizing Lenz's law. By monitoring the flow rate through each of the individual respective nozzle structures 222 of the one or more nozzle structures 222, determinations as to whether respective nozzle structures 222 of the one or more nozzle structures 222 are to be cleaned or replaced occur in a more timely manner such that respective layers formed on a respective surface of a workpiece are deposited even and level within selected tolerances. Furthermore, by having more accurate determinations of appropriate flow in real time, the respective nozzle structures 222 of the one or more nozzle structures 222 are more quickly cleaned (e.g., condensate build up) or replaced preventing the formation of uneven or unlevel layers reducing a number of out of tolerance semiconductor devices output by the FAB reducing waste costs.

FIG. 3D is a bottom view of the showerhead 210 as shown in FIG. 3A with the electromagnetic strips 224 hidden, in accordance with some embodiments. A dotted circle 248 defines a central region 250 within the dotted circle 248 and a peripheral region 252 outside of the dotted circle 248. The respective nozzle structures 222 within the dotted circle are utilized to form a central portion of one or more respective layers that are formed on the surface 105 of the workpiece 103, and the respective nozzle structures 222 outside the dotted circle 248 are utilized to form a peripheral portion of the one or more respective layers that are formed on the surface 105 of the workpiece 103. The peripheral portion extends around the central portion.

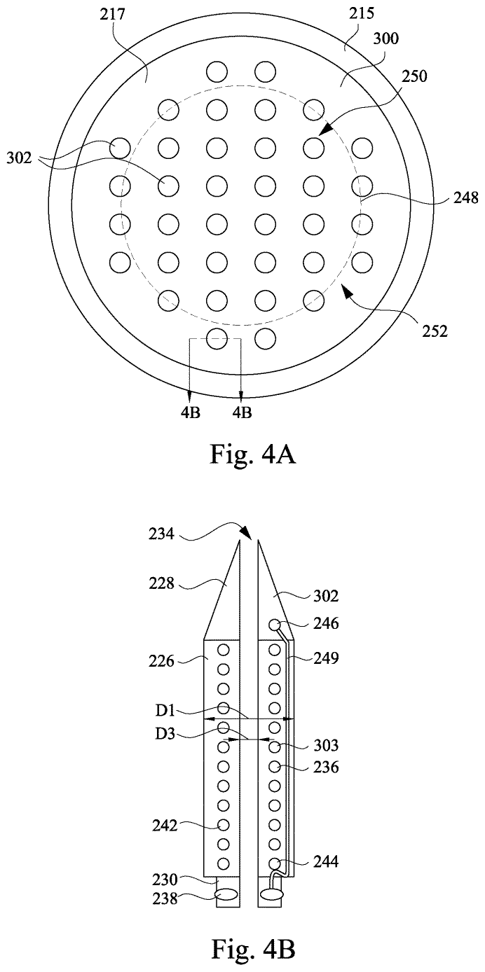

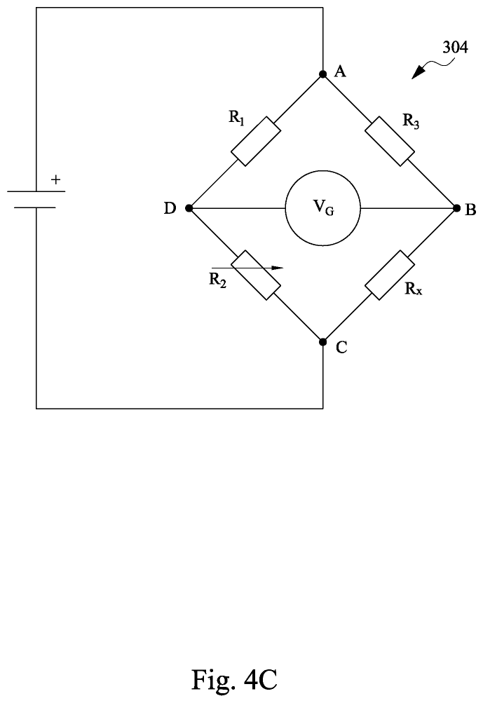

FIG. 4A is a top view of an alternative embodiment of a showerhead 300, in accordance with some embodiments. FIG. 4B is a cross-sectional zoomed in, enhanced view of an alternative nozzle 302 of the alternative showerhead 300 taken along line 4B-4B as shown in FIG. 4A. FIG. 4C is a schematic diagram of a Wheatstone bridge circuit 304 of the alternative nozzle structure as shown in FIG. 4B of the alternative showerhead 300 as shown in FIG. 4A, in accordance with some embodiments.

This alternative embodiment of the showerhead 300 has several of the same or similar features of the showerhead 210 as shown in FIGS. 3A-3D. Accordingly, for these same or similar features between the showerhead 210 and the alternative showerhead 300, the same or similar reference numerals have been utilized to label these same or similar features in the showerhead 300. For the sake of simplicity and brevity of the present disclosure, the new or different features of the alternative showerhead 300 relative to the showerhead 210 will be the focus of the following discussion and the details of those same or similar features between the showerhead 210 and the alternative showerhead 300 may not be reproduced herein.

Unlike the showerhead 210, the showerhead 300 includes one or more nozzle structures 302. Unlike the one or more nozzle structures 222 that include the wire 246 that is configured to, in operation, be utilized to monitor changes in a magnetic or electric field to determine the flowrate through the nozzle structure 222, the one or more nozzles 302 include a wire 303 (see FIG. 4B of the present disclosure) that is utilized to monitor temperature changes in the respective nozzle body 226 of the respective nozzle structure 302. In other words, the one or more nozzle structures 302 are similar to the one or more nozzle structures 222, but, while the wire 236 is configured to, in operation, be utilized to detect a change in a magnetic or electric field to determine a flow rate through the respective nozzle structure 222, the wire 303 as shown in FIG. 4B is configured to, in operation, be utilized to detect a change in temperature to determine a flow rate through the respective nozzle structure 302. For example, the wire 303 as shown in FIG. 4B is part of or is the Wheatstone Bridge circuit 304 to detect the change in temperature in the respective nozzle structure 302 when fluid is being ejected from the orifice 234 of the respective nozzle structures 302.

In operation, when a fluid is passing through the orifice 234 of the nozzle body 226 of the nozzle structure 302, the wire 236 is utilized to measure temperature changes within the nozzle body 226 in real time to monitor a respective flow rate through each of the one or more nozzle structures 302 coupled to the showerhead 300. For example, the flow rate may be determined by utilizing the Wheatstone Bridge circuit that includes the wire 236. By monitoring the flow rate through each of individual respective nozzle structures 302 of the one or more nozzle structures 302, determinations as to whether respective nozzle structures 302 of the one or more nozzle structures 302 are to be cleaned or replaced occur in a more timely manner such that respective layers formed on a respective surface of a workpiece are deposited even and level within selected tolerances. Furthermore, by having more accurate determinations of appropriate flow in real time, the respective nozzle structures 302 of the one or more nozzle structures 302 are more quickly cleaned (e.g., condensate build up) or replaced preventing the formation of uneven or unlevel layers reducing a number of out of tolerance semiconductor devices output by the FAB reducing waste costs.

To prevent the low regions 110c, the respective nozzle structures 222 as shown in FIGS. 3A-3D, 4A, and 4B in the peripheral region 252 are selected and adjusted in position such that the low regions 110c of the one or more layers are not formed on the surface 105 of the workpiece 103. To prevent the high regions 110a, the respective nozzle structures 222 in the central region 250 as shown in FIGS. 3A-3C, 4A, and 4B are selected and adjusted in position such that the high regions 110a are not formed on the surface 105 of the workpiece 103. In other words, by optimizing and adjusting the respective nozzle structures 222 within the central region 250 and the peripheral region 252, the one or more layers formed on the surface 105 of the workpiece 103 are formed more even and level across the entirety of the surface 105 of the workpiece 103. Generally, it is considered more critical to make sure the low regions 110c are not present as the one or more layers formed on the surface 105 of the workpiece can be later planarized and leveled if there is enough of the one or more layers present in close proximity to the edge of the workpiece 103.

To prevent the low regions 110c and the high regions 110a, the position of the respective nozzle structures 222 is adjusted and customized. Similarly, the respective nozzle structures 222 are selected from a number of variously sized and shaped nozzles that are larger and smaller than each other and are configured to, in operation, eject different amounts of fluid at the surface 105 of the workpiece 103. In other words, each of the respective nozzle structures 222 is selected from variously sized and shaped nozzle structures such that the respective nozzle structures 222 have different sizes and shapes to eject different amounts of fluid towards the surface 105 of the workpiece 103.

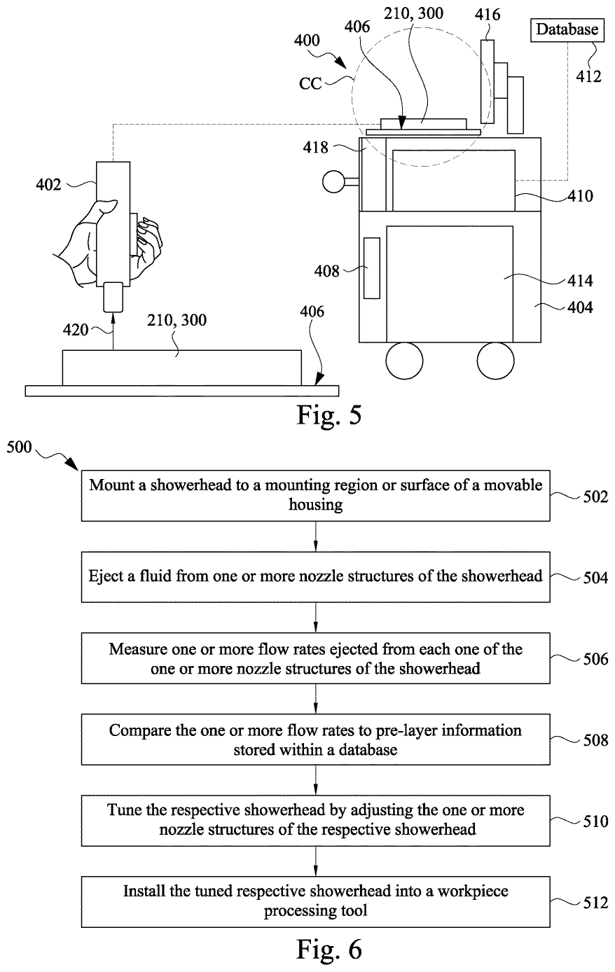

FIG. 5 is a diagram of a system 400 for pre-testing, calibrating, or testing the one or more nozzle structures 222 of the showerhead 210 or the one or more nozzle structures 302 of the alternative showerhead 300. The system 400 includes a flowrate measurement device 402 and a moveable housing 404. The movable housing 404 includes a mounting surface or region 406. The mounting surface or region 406 is in fluidic communication with a flowrate generation component 408 within the movable housing 404. A control box or processor 410 is within the movable housing 404 and is in electrical communication with a database 412. A nozzle storage compartment 414 is within the movable housing 404. A display 416 is in electrical communication with the control box or processor 410. A wireless receiver 418 is within the movable housing 404 and is in electrical communication with the flowrate measurement device 402 and in electrical communication with the control box or processor 410. The movable housing 404 is configured to, in operation, be movable throughout the FAB such that an operator can utilize the movable housing 404 to pre-test, calibrate, or test various respective showerheads 210, 300 to be utilized within various workpiece processing tools of the FAB.

The flowrate measurement device 402 is in wireless electrical communication with the wireless receiver 418 such that when the flowrate measurement device 402 is being utilized to measure a flowrate through a respective nozzle structure 222, 302, the measurement is output to the wireless receiver 418 wirelessly. The wireless receiver 418 then provides the measurement to the control box or processor 410.

The flowrate measurement device is selected from at least one of the following of a vortex sensor, a thermal mass flow meter, a doppler flow sensor, an ultrasonic flow sensor, or some other type of flow rate sensor that is capable of being utilized. Regardless of which one of these sensors is selected and utilized, the respective sensor is in electrical communication (e.g., through a wireless connection or wired connection) with the control box or processor 410. While in the embodiment as discussed herein this sensor is in electrical communication with the control box or processor 410 through the wireless receiver 418, in at least one alternative embodiment, this sensor may be in electrical communication through a physical wire with the control box and process 410 such that the wireless receiver 418 is not present.

The mounting surface or region 406 is configured to, in operation, receive the showerhead 210 or the alternative showerhead 300 for pre-testing, calibration, or testing. Once the respective showerhead 210, 300 is mounted to the mounting surface or region 406, the respective showerhead 210, 300 is in fluid communication with the flowrate generation component 408, which may be a pump or air compressor. The flowrate generation component 408 is configured to, in operation, generate a flow through the one or more nozzle structures 222, 302 coupled to the respective showerhead 210, 300 when the respective showerhead 210, 300 is mounted or coupled to the mounting surface or region 406.

The database 412 contains pre-layer information with respect to the one or more layers to be formed by the respective showerhead 210, 300 when installed into a workpiece processing tool. The pre-layer information within the database 412 is big-data of flowrate data collected from several operations of forming the one or more layers with the workpiece processing tool to optimize the evenness and levelness of the one or more layers to be formed on the surface 105 of the workpiece 103 when utilizing the respective showerhead 210, 300 mounted within the workpiece processing tool.

The nozzle storage compartment 414 contains and stores a number of variously sized and shaped nozzle structures with varying sizes and shapes (e.g., different dimensions, different orifice sizes, different profiles, different orifice shapes and sizes, or some other quality or quantity that may be utilized to adjust a flow ejected from the respective showerhead 210, 300). These variously sized and shaped nozzle structures (e.g., the one or more nozzle structures 222 and the one or more nozzle structures 302) are configured to, in operation, be mounted to the fluid openings 220 of the respective showerhead 210, 300.

The display 416 is configured to, in operation, output data and information such that an operator may readily pre-test, calibrate, or test the respective showerhead 210, 300 and the one or more nozzle structures 222, 302 coupled to the respective showerhead 210, 300. In other words, the display 416 may be a computer screen, a tablet screen, a TV screen, a computer monitor, or some other similar or like type of electronic display readily viewable by an operator of the system 400.

The left-hand side of FIG. 5 is a zoomed in and enhanced view of section CC of the respective showerhead 210, 300 when pre-testing, calibrating, or testing the respective showerhead 210, 300 when mounted or coupled to the mounting surface or region.

The control box 410 is configured to, in operation, be in electrical communication with the wireless receiver 418 and receive the measurements as measured by the flowrate measurement device 402. The control box 410 is in electrical communication with the database 412, which may be stored at a location external to the movable housing 404. The control box 410, which may contain or be a processor, is configured to, in operation, compare the pre-layer information stored in the database 412 to the measurement data collected by the flowrate measurement device 402.

FIG. 6 is a flowchart 500 for utilizing the system 400 as shown in FIG. 5 for performing a method of pre-testing, calibrating, or testing the respective showerhead 210, 300. The flowchart 500 includes a first step 502, a second step 504, a third step 506, a fourth step 508, a fifth step 510, and a sixth step 512. The following discussion of the flowchart 500 will be focused on discussing pre-testing and calibrating the respective showerhead 210, 300 before installing the showerhead 210, 300 within a respective workpiece processing tool. The details of the respective steps of the flowchart 500 will be discussed with respect to the details and features of the system 400.

In the first step 502, the respective showerhead 210, 300 is mounted to the mounting surface or region 406. By mounting the respective showerhead 210, 300 to the mounting surface or region 406, the fluid openings 220 of the respective showerhead 210, 300 are brought into fluid communication with the flowrate generation component 408. As the fluid openings 220 are in fluid communication with the flowrate generation component 408, the one or more nozzle structures 222 mounted or coupled to the fluid openings 220 are in fluid communication with the flowrate generation component 408 through the fluid openings 220.

After the respective showerhead 210, 300 has been mounted to the mounting surface or region 406, in the second step 504 the flowrate generation component 408 is activated (i.e., turned “on”) generating a fluid (e.g., air) to be introduced into the fluid openings 220 and ejected from the one or more nozzle structures 222 of the respective showerhead 210, 300. The flowrate of this fluid into the fluid openings 220 and ejected from the one or more nozzle structures 222 is represented by an arrow 420 as shown in FIG. 5. While only this one arrow 420 is shown in FIG. 5, it will be readily appreciated that in some situations this fluid (e.g., air) is being ejected from all of the one or more nozzle structures 222 simultaneously.

After the second step 504 in which the fluid is ejected from the one or more nozzle structures 222, in the third step 506 an operator aligns the flowrate measurement device 402 with a respective nozzle structure 222 of the one or more nozzle structures 222 and utilizes the flowrate measurement device 402 to measure the flowrate being ejected from the respective nozzle structure 222 of the one or more nozzle structures 222. In this embodiment of the system 400, the flowrate measurement device 402 is a handheld device that is positioned by hand over the respective nozzle structure 222 of the one or more nozzle structures 222 by the operator. The flowrate measurement device 402 then collects data with respect to the flowrate being ejected from the respective nozzle 222 of the one or more nozzle structures 222 of the respective showerhead 210, 300. The operator performs this process multiple times to collect the flowrate measurement with respect to each respective nozzle structure 222 of the one or more nozzle structures 222 by aligning the flowrate measurement device 402 over each respective nozzle structure 222 of the one or more nozzle structures 222 in succession.

After the third step 506 in which the flowrate measurement is collected for each respective nozzle structure 222 of the one or more nozzle structures 222, in the fourth step 508 the measurements of the flowrates of each respective nozzle structure 222 of the one or more nozzle structures 222 is sent to the control box 410, which may be a processor. The control box 410 receives the pre-layer information within the database 412. The pre-layer information is big-data collected from testing several respective showerheads 210, 300 over time and used to determine optimal flowrates for each respective nozzle structure 222 of the one or more nozzle structures 222. The pre-layer information may be flowrate patterns or optimized individual flowrates for each respective nozzle structure 222 of the one or more nozzle structures such that the one or more nozzle structures 222 are in optimal positions and provide optimal flowrates to reduce the likelihood of forming the low regions 110c of the one or more layers 108 on the surface 105 of the workpiece 103, reduce the likelihood of forming the high regions 110a, or reduce the likelihood of forming both the low regions 110c and the high regions 110a resulting in the one or more layers 108 being formed more even and level on the surface 105 of the workpiece 103.

In comparing the pre-layer information to the measured flowrates ejected from each of the respective nozzle structures 222 of the one or more nozzle structures 222, the control box 410 outputs comparison results to the display 416. When a respective nozzle structure 222 is operating outside of selected tolerances as set forth in the pre-layer information, the display 416 outputs an indication that the respective nozzle structure 222 is not operating within the selected tolerances. When the respective nozzle structure 222 is operating within selected tolerances as set forth in the pre-layer information, the display outputs an indication that the respective nozzle structure 222 is operating within the selected tolerances.

As the operator collects the flowrate measurements for each of the respective nozzle structures 222 of the one or more nozzle structures 222, in some situations, the database 412 collects these measurements to continually update the pre-layer information within the database that may be utilized to further refine the pre-layer information to provide more accurate calibration, pre-testing or testing of the respective showerheads 210, 300.

After the fourth step 508 in which the operator measures the flowrate through each of the respective nozzle structures 222 of the respective showerhead 210, 300 and the control box 410 compares the flowrate measurements to the pre-layer information, in the fifth step 510 the operator manually tunes or calibrates the respective showerhead 210, 300. The operator manually tunes the respective showerhead by any of the following of removing respective nozzle structures 222 of the one or more nozzle structures 222, repositioning respective nozzle structures 222 of the one or more nozzle structures 222, replacing respective nozzle structures 222 of the one or more nozzle structures 222, or by some other similar or like type of action by the operator to manually tune the respective showerhead 210, 300 such that the showerhead 210, 300 outputs the desired flow pattern as set by the pre-layer information stored within the database 412. For example, when it is determined that the respective nozzle structure 222 is not outputting an appropriate flowrate within selected tolerances, the operator may remove the respective nozzle structure 222 from the respective showerhead 210, 300 and replace it with another nozzle structure 222 that has the same size and shape or has a different size and shape. Alternatively, the operator may adjust the position of the respective nozzle structure 222 by removing the respective nozzle structure 222 from a first fluid opening 220 of the one or more fluid openings 220 and inserting the respective nozzle structure 222 into a second fluid opening 220 of the one or more fluid openings 220. After the operator has tuned the showerhead 210, 300 based on the information output on the display 416, the operator re-performs the third step 506 and the fourth step 508 at least for the respective nozzle structures that have been adjusted to tune the respective showerhead 210, 300.

When tuning or calibrating the one or more nozzle structures 222 of the respective showerhead 210, 300, the operator has access to variously sized and shaped nozzle structures that are stored within the nozzle storage compartment 414 that can be mounted or coupled to the respective showerhead 210, 300 to calibrate the respective showerhead 210, 300. The variously sized and shaped nozzle structures stored within the nozzle storage compartment 414 may have variously sized and shaped nozzle bodies that are different from each other, may have variously sized orifices that are different from each other, or may have some other variously sized and shaped features such that these variously sized and shaped nozzle structures may be mounted and coupled to the respective showerhead 210, 300 to tune and calibrate the respective showerheads 210, 300.

After the fifth step 510 in which the respective showerhead 210, 300 has been tuned by adjusting the one or more nozzle structures 222 to output the desired flow pattern from the respective showerhead 210, 300 based on the comparison with the pre-layer information stored in the database 412, in a sixth step 512, the respective showerhead 210, 300 is installed in a workpiece processing tool. The showerhead 210, 300 may be installed into the workpiece processing tool to replace a showerhead previously utilized within the workpiece processing tool that needs to be cleaned or replaced.

Pre-testing, tuning, and calibrating the one or more nozzle structures 222 of the respective showerhead 210, 300 reduces downtime of the workpiece processing tools. For example, the method as set forth and discussed above with respect to the flowchart 500 is performed in advance of the showerhead 210, 300 being installed into the workpiece processing tool. By performing this pre-test and calibration in advance of installing the respective showerhead 210, 300, which may be a replacement showerhead to replace a showerhead already within the workpiece processing tool, the operator may then stop operation of the workpiece processing tool, quickly install the replacement and pre-calibrated showerhead 210, 300, and then restart operation of the workpiece processing tool. Once the replacement pre-calibrated showerhead is installed, the old showerhead may be cleaned or may have maintenance performed on the old showerhead to pre-test and pre-calibrate the old showerhead before being installed in another workpiece processing tool. This pre-testing and pre-calibration of the respective showerhead 210, 300 increases uptime of the workpiece processing tools running within the FAB by reducing downtime to perform maintenance on the workpiece processing tools increasing a yield number of the FAB.

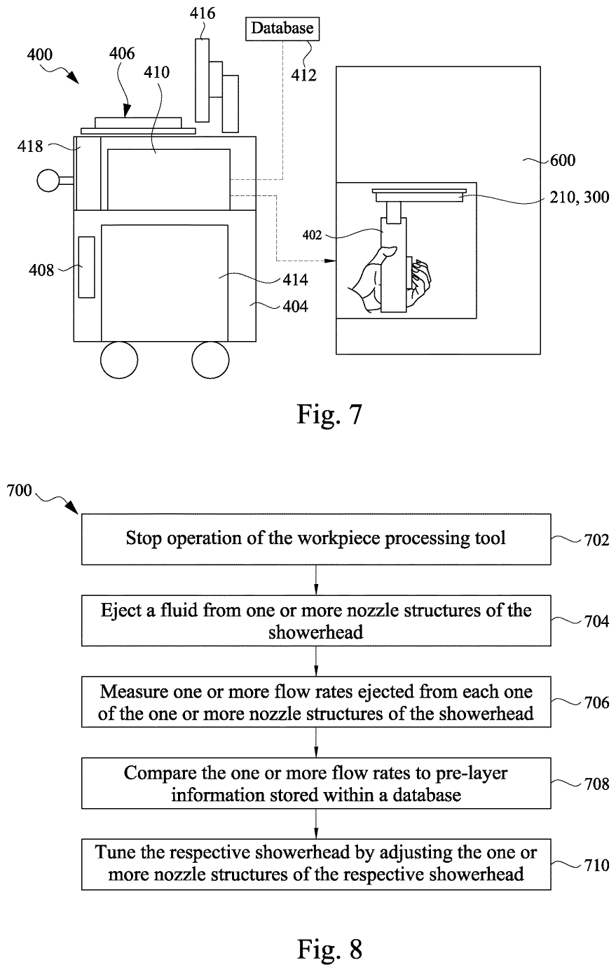

FIG. 7 is directed to the system 400 as shown in FIG. 5 being utilized to pre-test or test a respective showerhead 210, 300 already installed within a workpiece processing tool 600 that is configured to, in operation, form the one or more layers 108 on the surface 105 of the workpiece 103. As the details of the system 400 were discussed in detail with respect to FIG. 5 of the present disclosure, for the sake of brevity and simplicity of the present disclosure, the details of the system 400 are not fully reproduced fully herein. As shown in FIG. 7, the respective showerhead 210, 300 is already installed within the workpiece processing tool 600. For example, the showerhead 210, 300 is already installed within the process chamber 213 of the workpiece processing tool 600.

FIG. 8 is a flowchart 700 of a method of testing or calibrating the respective showerhead 210, 300 already installed in the workpiece processing tool 600. The flowchart 700 includes a first step 702, a second step 704, a third step 706, a fourth step 708, and a fifth step 710. The following discussion of the flowchart 700 will be focused on discussing testing and calibrating the respective showerhead 210, 300 when it is installed in the showerhead 210, 300 within the workpiece processing tool 600. The details of these steps will be discussed with respect to the details and features of the system 400.

In the first step 702, the operator stops operation of the workpiece processing tool 600 such that the operator can access the process chamber 213 in which the respective showerhead 210, 300 is present. The respective showerhead 210, 300 may have been previously utilized within the workpiece processing tool 600 to form the one or more layers 108 on the surface 105 of the workpiece 103. Once the operator stops operation of the workpiece processing tool 600, the operator accesses the process chamber 213.

After the first step 702 in which the operator stops operation of the workpiece processing tool 600, in the second step 704 the operator either brings the flowrate generation component 408 into fluid communication with the respective showerhead 210, 300 or another flowrate generation component, which is within the workpiece processing tool 600, is already in fluid communication with the respective showerhead 210, 300. The flowrate generation component 408 or the flowrate generation component within the workpiece processing tool 600 is activated (e.g., turned “on”) to eject a fluid (e.g., air) from the one or more nozzle structures 222 of the respective showerhead 210, 300 similar to the ejection of the fluid from the respective showerhead 210, 300 as discussed earlier herein with respect to the second step 504 of the method of the flowchart 500.

After the second step 704 in which the fluid (e.g., air) is ejected from the one or more nozzle structures 222 of the respective showerhead 210, 300 within the workpiece processing tool 600, in the third step 706 the operator aligns the flowrate measurement device 402 with a respective nozzle structure 222 of the one or more nozzle structures 222 and utilizes the flowrate measurement device 402 to measure the flowrate being ejected from the respective nozzle structure 222 of the one or more nozzle structures 222 of the respective showerhead 210, 300 within the workpiece processing tool 600. In this embodiment of the system 400, the flowrate measurement device 402 is a handheld device that is positioned by hand over the respective nozzle structure 222 of the one or more nozzle structures 222 by the operator. The flowrate measurement device 402 then collects data with respect to the flowrate being ejected from the respective nozzle 222 of the one or more nozzle structures 222 of the respective showerhead 210, 300. The operator performs this process multiple times to collect the flowrate measurement with respect to each respective nozzle structure 222 of the one or more nozzle structures 222 by aligning the flowrate measurement device 402 over each respective nozzle structure 222 of the one or more nozzle structures 222 in succession.

After the third step 706 in which the flowrates through the one or more nozzle structures 222 of the respective showerhead 210, 300 are measured, in the fourth step 708 the measurements of the flowrates of each respective nozzle structure 222 of the one or more nozzle structures 222 are sent to the control box 410, which may be a processor. The control box 410 receives the pre-layer information within the database 412. The pre-layer information is big-data collected from testing several respective showerheads 210, 300 over time and used to determine optimal flowrates for each respective nozzle structure 222 of the one or more nozzle structures 222. The pre-layer information may be flowrate patterns or optimized individual flowrates for each respective nozzle structure 222 of the one or more nozzle structures such that the one or more nozzle structures 222 are in optimal positions and provide optimal flowrates to reduce the likelihood of forming the low regions 110c of the one or more layers 108 on the surface 105 of the workpiece 103, reduce the likelihood of forming the high regions 110a, or reduce the likelihood of forming both the low regions 110c and the high regions 110a resulting in the one or more layers 108 being formed more even and level on the surface 105 of the workpiece 103.

In comparing the pre-layer information to the measured flowrates ejected from each of the respective nozzle structures 222 of the one or more nozzle structures 222, the control box 410 outputs comparison results to the display 416. When a respective nozzle structure 222 is operating outside of selected tolerances as set forth in the pre-layer information, the display 416 outputs an indication that the respective nozzle structure 222 is not operating within the selected tolerances. When the respective nozzle structure 222 is operating within selected tolerances as set forth in the pre-layer information, the display outputs an indication that the respective nozzle structure 222 is operating within the selected tolerances.

As the operator collects the flowrate measurements for each of the respective nozzle structures 222 of the one or more nozzle structures 222, in some situations, the database 412 collects these measurements to continually update the pre-layer information within the database that may be utilized to further refine the pre-layer information to provide more accurate calibration, pre-testing or testing of the respective showerhead 210, 300.

After the fourth step 708 in which the operator measures the flowrate through each of the respective nozzle structures 222 of the respective showerhead 210, 300 and the control box 410 compares the flowrate measurements to the pre-layer information, in a fifth step 710 the operator manually tunes or calibrates the respective showerhead 210, 300. The operator manually tunes the respective showerhead by any of the following of removing respective nozzle structures 222 of the one or more nozzle structures 222, repositioning respective nozzle structures 222 of the one or more nozzle structures 222, replacing respective nozzle structures 222 of the one or more nozzle structures 222, or by some other similar or like type of action by the operator to manually tune the respective showerhead 210, 300 such that the showerhead 210, 300 outputs the desired flow pattern as set by the pre-layer information stored within the database 412. For example, when it is determined that the respective nozzle structure 222 is not outputting an appropriate flowrate within selected tolerances, the operator may remove the respective nozzle structure 222 from the respective showerhead 210, 300 and replace it with another nozzle structure 222 that has the same size and shape or has a different size and shape. Alternatively, the operator may adjust the position of the respective nozzle structure 222 by removing the respective nozzle structure 222 from a first fluid opening 220 of the one or more fluid openings 220 and inserting the respective nozzle structure 222 into a second fluid opening 220 of the one or more fluid openings 220. After the operator has tuned the showerhead 210, 300 based on the information output on the display 416, the operator re-performs the third step 506 and the fourth step 508 at least for the respective nozzle structures that have been adjusted to tune the respective showerhead 210, 300.

When tuning or calibrating the one or more nozzle structures 222 of the respective showerhead 210, 300, the operator has access to variously sized and shaped nozzle structures that are stored within the nozzle storage compartment 414 that can be mounted or coupled to the respective showerhead 210, 300 to calibrate the respective showerhead 210, 300. The variously sized and shaped nozzle structures stored within the nozzle storage compartment 414 may have variously sized and shaped nozzle bodies that are different from each other, may have variously sized orifices that are different from each other, or may have some other variously sized and shaped features such that these variously sized and shaped nozzle structures may be mounted and coupled to the respective showerhead 210, 300 to tune and calibrate the respective showerhead 210, 300.

Alternatively, instead of tuning or calibrating the respective showerhead 210, 300 within the workpiece processing tool 600, the operator may remove the respective showerhead 210, 300 operating outside selected tolerances and replace it with an already pre-tested and pre-calibrated showerhead 210, 300 that was pre-tested and pre-calibrated utilizing the method of the flowchart 500 to reduce downtime of the workpiece processing tool 600. Once the pre-tested and pre-calibrated showerhead 210, 300 is installed within the workpiece processing tool 600, the operator re-activates the workpiece processing tool 600 such that the workpiece processing tool 600 continues to process workpieces passing through the workpiece processing tool 600. For example, the workpiece processing tool 600 may be configured to, in operation, form the one or more layers 108 on the surface 105 of the workpiece 103.

In view of the above discussions with respect to the methods of the flowcharts 500, 700, the downtime of the workpiece processing tool 600 is reduced and the levelness and the evenness of the one or more layers 108 formed on the surface 105 of the workpiece 103 is improved. This reduced downtime allows for the FAB to output a greater yield of semiconductor devices, and the increased evenness and levelness in forming the one or more layers 108 decreases the number of semiconductor devices that are manufactured outside of selected tolerances reducing waste costs to operate the FAB.

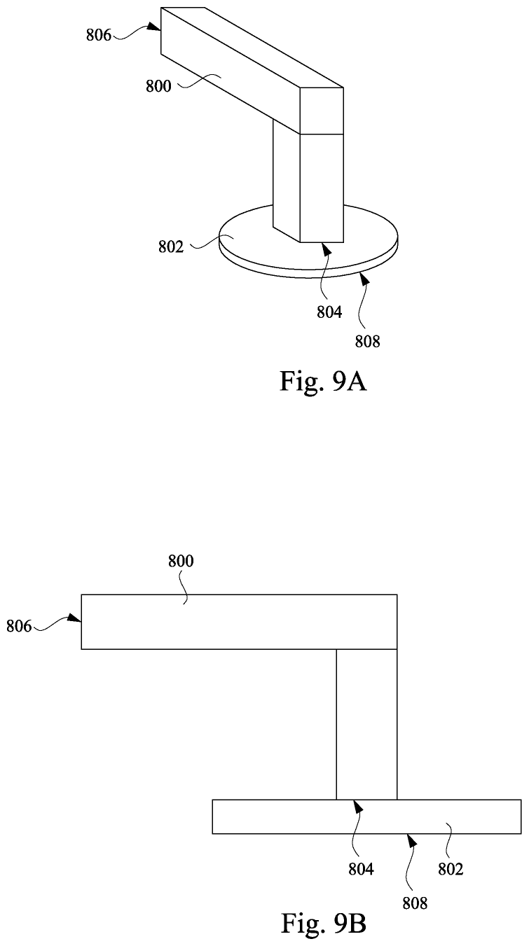

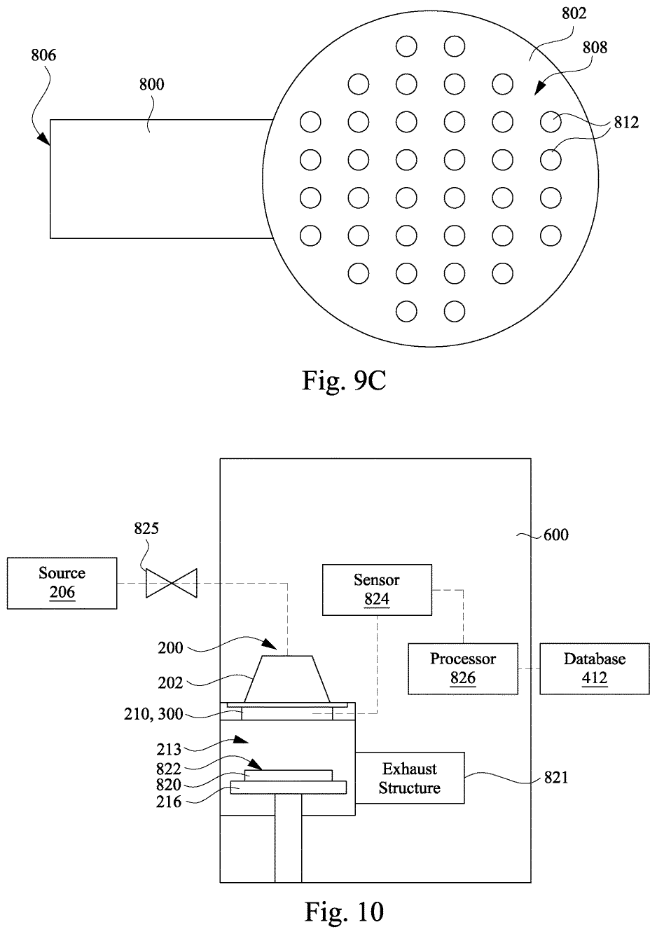

FIG. 9A is directed to a perspective view of a robotic arm 800 for pre-testing, calibrating, or testing the respective showerhead 210, 300 either when mounted to the mounting region or surface 406 of the system 400 or when already installed within the workpiece processing tool 600. FIG. 9B is a side view of the robotic arm 800. FIG. 9C is a bottom end of an end effector 802 at an end effector end 804 of the robotic arm 800. While not shown, in at least some embodiments, the robotic arm 800 is attached to the movable housing 404 and is controllable by controls present along and accessible at an exterior of the movable housing 404 such that an operator can control the robotic arm 800. In other words, the robotic arm 800 can replace the flowrate measuring device 402. A mountable end 806 of the robotic arm 800 is at an opposite end of the robotic arm 800 relative to the end effector end. The mountable end 806 is coupled to or mounted to the movable housing 404 of the system 400. The robotic arm 800 is articulable relative to the movable housing 404 such that the end effector 802 is readily movable to align the end effector 802 with the respective showerhead 210, 300. The end effector 802 includes a flowrate measuring surface 808.

As shown in FIG. 9C, the end effector 802 includes one or more measuring flowrate openings 812 at the flowrate measuring surface 808. The one or more flowrate openings 812 are capable of measuring flowrates output by the one or more nozzle structures 222 of the respective showerhead 210, 300 at the same time. The control box 410 receives the flowrates measured by the end effector 802 and utilizes that information to carry out the respective steps in the methods in the flowcharts 500, 700 as discussed earlier herein. In other words, instead of having to measure the flowrate ejected through each individual nozzle structure 222 of the one or more nozzle structures individually by utilizing the handheld flowrate measuring device 402, the end effector 802 is configured to, in operation, measure each individual flowrate output by each respective nozzle structure 222 of the one or more nozzle structures 222 simultaneously or measure all of the flowrates output by the one or more nozzle structures 222 to provide an overall measurement of a flowrate pattern output by the one or more nozzle structures of the respective showerhead 210, 300. By utilizing the robotic arm 800 with the end effector 802, the methods as discussed earlier herein with respect to the flowcharts 500, 700 are capable of being carried out more rapidly as the operator does not need to measure each individual flowrate from each individual nozzle structure 222 of the one or more nozzle structures 222 of the respective showerhead 210, 300. This increased rapidity of measuring the flowrates, allows for the operator to more quickly and efficiently tune and calibrate the respective showerhead 210, 300 before being installed into the workpiece processing tool 600 or while installed within the workpiece processing tool 600.

Each one of the measuring flowrate openings 812 at the flowrate measuring surface 808 corresponds to a flowrate measurement device (not shown) that is selected from at least one of the following of a vortex sensor, a thermal mass flow meter, a doppler flow sensor, an ultrasonic flow sensor, or some other type of flow rate sensor that is capable of being utilized. In other words, in at least one embodiment of the end effector 802, there is a one-to-one relationship between the measuring flowrate openings 812 and the selected sensors for measuring the flowrates through each of the respective nozzle structures 222 of the one or more nozzle structures 222. Regardless of which one of these sensors is selected and utilized, the respective sensor is in electrical communication (e.g., through a wireless connection or wired connection) with the control box or processor 410. While in the embodiment as discussed herein this sensor is in electrical communication with the control box or processor 410 through the wireless receiver 418, in at least one alternative embodiment, this sensor may be in electrical communication through a physical wire with the control box and process 410 such that the wireless receiver 418 is not present.

FIG. 10 is a side view of the workpiece processing tool 600 including one of the respective showerheads 210, 300 as discussed earlier herein, in accordance with some embodiments. The workpiece processing tool 600 includes the assembly 200. While the workpiece processing tool 600 includes the assembly 200, only some of the features of the assembly 200 are shown in FIG. 10 for the sake of simplicity and ease of understanding. As shown in FIG. 10, a workpiece 820 (e.g., a silicon wafer), which may be the same or similar to the workpiece 103 as discussed earlier herein, is on the workpiece surface 219 of the pedestal 216. The workpiece 820 is overlapped by the showerhead 210, 300, which has been pre-calibrated and tuned in line with the earlier discussions herein with respect to FIGS. 5-9C of the present disclosure. The workpiece processing tool 600 further includes an exhaust structure 821 such that exhaust or off-gassing when forming one or more layers of material on a surface 822 of the workpiece 820 is allowed to escape from the process chamber 213. The exhaust structure 821 may be essentially the same or similar to the exhaust structure 102 as discussed earlier herein. The workpiece processing tool further includes one or more sensors 824, which may be one or more of vortex sensors, thermal mass flow meters, a doppler flow sensors, an ultrasonic flow sensors, or some other type of flow rate sensor that is capable of being utilized to monitor flowrates output from the one or more nozzle structures 222, and a processor 826 that is in electrical communication with the one or more sensors 824. The one or more sensors 824 are configured to, in operation, monitor respective flowrates output from the one or more nozzle structures 222 of the respective showerhead 210, 300. The processor 826 is in electrical communication with the database 412. The database 412 is configured to, in operation, provide pre-layer information to the processor 826 such that the processor 826 can monitor the respective flowrates output by the one or more nozzle structures 222 or a flowrate pattern output by the one or more nozzle structures 222.

The workpiece processing tool 600 further includes a valve 825 that is along a fluid pathway between the assembly 200 and the source 206. The valve 825 is configured to, in operation, be opened and closed to control the material being provided from the source 206 to the assembly 200 through the fluid pathway.

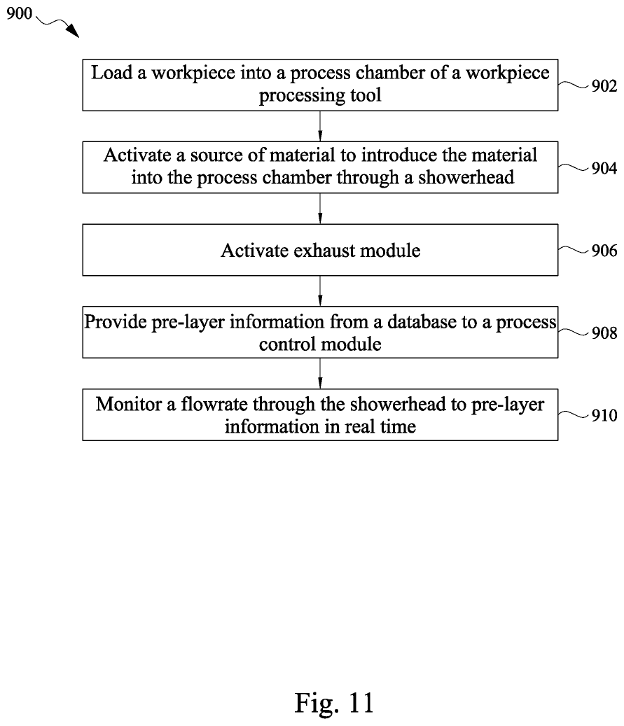

FIG. 11 is a flowchart 900 for utilizing the workpiece processing tool 600 including the respective showerhead 210, 300, as shown in FIG. 10, for performing a method of forming one or more layers on the surface 822 of the workpiece 820, in accordance with some embodiments. The flowchart 900 includes a first step 902, a second step 904, a third step 906, a fourth step 908, and a fifth step 910.

In the first step 902, the workpiece 820 is inserted into the process chamber 213 and placed on the workpiece surface 219 of the pedestal 216. Once the workpiece 820 is placed on the workpiece surface 219 of the pedestal 216, the pedestal 216 may be raised or lowered to optimize the position of the pedestal 216 relative to the respective showerhead 210, 300.

After the first step 902 in which the workpiece 820 has been positioned on the workpiece surface 219 of the pedestal 216, in a second step 904 the valve 825 is opened such that a material from the source 206 passes through the valve 825 along the fluid pathway and is introduced to the assembly 200 within the workpiece processing tool 200. The material is converted into a plasma within the dome 202 of the assembly 200. After the material has been converted into plasma by passing through the assembly 200, the plasma is ejected from the one or more nozzle structures 222 of the respective showerhead 210, 300 into the process chamber 213 and directed at the surface 822 of the workpiece 820.

After the second step 904 is initiated or simultaneously with the second step 904 in which the valve 825 is opened, the material from the source 206 is converted into plasma by passing through the assembly 200, and the plasma is ejected from the one or more nozzle structures 222 of the respective showerhead 210, 300, in a third step 906 the exhaust structure 821 is activated such that exhaust or off-gassing generated when depositing the plasma material onto the surface 822 of the workpiece 820 is allowed to escape from the process chamber 213. The exhaust structure 821 may include a fan (not shown) that is activated to generate a flow through the process chamber to direct the exhaust away and out of the process chamber 213 through the exhaust structure 821.

After the second step 904 and the third step 906 or simultaneously with the second step 904 and third step 906 in which the plasma material is generated and ejected from the one or more nozzle structures 222 and the exhaust structure 821 is activated, in a fourth step 908 a processor 826 receives pre-layer information from the database 412 and collects information from the one or more sensors 824 that measure the flowrate of the one or more nozzle structures 222.

After the fourth step 908 in which the pre-layer information from the database 412 is provided to the processor 826, in a fifth step 910 the one or more sensors 824 measure the flowrate through each of the individual nozzle structures 222 of the one or more nozzle structures 222, measures the flowrate pattern generated by all of the nozzle structures 222 together, or both. The processor 826 receives these measurements from the one or more sensors 824. In some embodiments, the processor 826 outputs the data received from the one or more sensors 824 to the database 412 such that the database can utilize this collected information to further refine algorithms in determining optimized pre-layer information based on big data to further optimize the evenness and levelness in forming the one or more layers on the surface 822 of the workpiece 820.

After the fourth step 908 in which the processor 826 receives the pre-layer information from the database 412, in a fifth step 910 the processor compares the pre-layer information from the database 412 to the respective flowrates measured by the one or more sensors 824 in real time. During this real time monitoring, if the processor 826 determines that the respective flowrates match up with the pre-layer information provided by the database 412, the processor 826 does not output a warning indication as the one or more nozzle structures 222 are providing flowrates within selected tolerances to optimize the evenness or levelness of the one or more layers being formed on the surface 822 of the workpiece 820. Alternatively, during this real time monitoring, if the processor 826 determines that respective flowrates do not match up with the pre-layer information provided by the database, the processor 826 outputs the warning indication to inform an operator that the respective flowrates are not within selected tolerances. When this warning occurs, the operation of the workpiece processing tool 600 can be stopped to prevent forming more of the one or more layers on successive workpieces to prevent forming semiconductor devices functioning outside of selected tolerances. Preventing manufacturing semiconductor devices outside of selected tolerances reduces waste costs in operating the FAB in which the workpiece processing tool 600 is present.

When the operator has stopped operation of the workpiece processing tool 600 due to the processor 826 outputting the warning indication, the operator can either replace the showerhead 210, 300 with another showerhead 210, 300 that has already been pre-tested and calibrated, for example, by utilizing the method of the flowchart 500 as shown in FIG. 6 of the present disclosure, or the operator can re-tune the one or more nozzle structures 222 of the respective showerhead 210, 300, for example, by utilizing the method of the flowchart 700 as shown in FIG. 8 of the present disclosure.

When replacing the showerhead 210, 300 within the workpiece processing tool 600 with the pre-tested and calibrated replacement showerhead 210, 300 utilizing the method as shown in the flowchart 500, the downtime of the workpiece processing tool 600 is reduced as the pre-tested and calibrated replacement showerhead 210, 300 is already tuned and ready to be inserted into the workpiece processing tool 600. Furthermore, by replacing the showerhead 210, 300 no longer functioning within selected tolerances with the pre-tested and calibrated replacement showerhead 210, 300, waste costs of the FAB are reduced as the one or more layers formed on successive workpieces remain even and level within selected tolerances reducing a number of manufactured semiconductor devices that function outside of selected tolerances.

When retuning the showerhead 210, 300 no longer functioning within the workpiece processing tool 600 with the method as shown in the flowchart 700, waste costs of the FAB are reduced as the one or more layers formed on successive workpieces remain even and level within selected tolerances reducing a number of manufactured semiconductor devices that function outside of selected tolerances.

At least one embodiment of a device of the present disclosure is summarized as including: a head including a plurality of fluid openings; a plurality of nozzle structures coupled to the head, each respective nozzle structure of the plurality of nozzle structures being in fluid communication with a corresponding fluid opening of the plurality of fluid openings, each of respective nozzle structure of the plurality of nozzle structures is configured to, in operation, be removable and replaceable relative to the head, each respective nozzle structure of the plurality of nozzle structures including: a nozzle body including a first end and a second end opposite to the first end; a fluid channel extending through the nozzle body from the first end to the second end; and a flowrate monitoring structure embedded within the nozzle body.

At least one embodiment of a method of the present disclosure is summarized as including: measuring a respective flowrate of a plurality of flowrates through each respective nozzle structure of a plurality of nozzle structures that are removably coupled to a head body of a showerhead, each respective nozzle structure of the plurality of nozzle structures is in fluid communication with a respective fluid opening of a plurality of fluid openings in the head body of the showerhead; comparing the plurality of flowrates to wafer pre-layer information stored in a database; and tuning the showerhead responsive to determining, based on the comparison, that at least one of the plurality of flowrates are out of tolerance with respect to the wafer pre-layer information stored in the database.

At least one embodiment of a system of the present disclosure is summarized as including: a showerhead including: a head body including a plurality of fluid openings; a plurality of nozzle structures coupled to the head body, each respective nozzle structure of the plurality of nozzle structures being in fluid communication with a corresponding fluid opening of the plurality of fluid openings, each respective nozzle structure of the plurality of nozzle structures are configured to, in operation, be removable and replaceable relative to the head body, each respective nozzle structure of the plurality of nozzle structures including: a nozzle body including a first end and a second end opposite to the first end; a fluid channel extending through the nozzle body from the first end to the second end; and a flowrate monitoring structure embedded within the nozzle body; a pedestal configured to, in operation, be moved from a lowered position and a raised position, the pedestal being in relatively closer proximity to the shower head when in the raised position; and a workpiece on the pedestal, wherein: when the pedestal is in the raised position and the showerhead is activated, a layer of material is formed on a surface of the workpiece.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device, comprising:
a head including a first surface, a second surface opposite to the first surface, and a plurality of fluid openings extending between the first surface and the second surface; and
a plurality of nozzle structures coupled to the head, each respective nozzle structure of the plurality of nozzle structures being received in a corresponding fluid opening of the plurality of fluid openings, each respective nozzle structure of the plurality of nozzle structures being removable and replaceable relative to the head, each respective nozzle structure of the plurality of nozzle structures including:
a nozzle body having a first end and a second end opposite to the first end; and
a fluid channel extending through the nozzle body from the first end to the second end.

2. The device of claim 1, wherein:
the plurality of fluid openings includes a first number of fluid openings;
the plurality of nozzle structures includes a second number of nozzle structures; and
the first number of fluid openings is greater than the second number of nozzle structures.

3. The device of claim 1, wherein the head further includes a central portion and a peripheral portion, and at least one nozzle structure of the plurality of nozzle structures is coupled to a fluid opening in the central portion and at least one nozzle structure of the plurality of nozzle structures is coupled to a fluid opening in the peripheral portion.

4. The device of claim 1, wherein the plurality of nozzle structures further includes a first type of nozzle structures having a first orifice dimension and a second type of nozzle structures having a second orifice dimension different from the first orifice dimension.

5. The device of claim 1, wherein each respective nozzle structure of the plurality of nozzle structures further includes a flowrate monitoring structure embedded within the nozzle body.

6. The device of claim 5, wherein the flowrate monitoring structure includes a coil within the nozzle body, the coil wrapping around the fluid channel, and the coil being configured to, in operation, measure a magnetic field to monitor a flowrate of a fluid passing through the fluid channel.

7. The device of claim 5, wherein the flowrate monitoring structure includes a Wheatstone bridge sensor configured to, in operation, measure a temperature of the respective nozzle structure to determine a flowrate through the fluid channel of the respective nozzle structure.

8. A device, comprising:
a head including a plurality of fluid openings;
a plurality of nozzle structures coupled to the head, each respective nozzle structure of the plurality of nozzle structures being in fluid communication with a corresponding fluid opening of the plurality of fluid openings, each respective nozzle structure of the plurality of nozzle structures being removable and replaceable relative to the head, each respective nozzle structure of the plurality of nozzle structures including:
a nozzle body comprising a first end and a second end opposite to the first end;
a fluid channel extending through the nozzle body from the first end to the second end; and
a coil embedded within the nozzle body, the coil wrapping around the fluid channel; and
a plurality of electromagnetic strips positioned along the head.

9. The device of claim 8, wherein the coil wraps around the fluid channel at least twice.

10. The device of claim 8, wherein the plurality of electromagnetic strips are configured to, in operation, be energized to provide contactless sensing of a flowrate through the fluid channel of each respective nozzle structure of the plurality of nozzle structures.

11. The device of claim 8, wherein the coil is in electrical communication with a processor configured to, in operation, receive measurements of a magnetic field from the coil to determine a flowrate of a fluid passing through the fluid channel.

12. The device of claim 8, wherein:
the plurality of fluid openings includes a first number of fluid openings;
the plurality of nozzle structures comprises a second number of nozzle structures; and
the first number of fluid openings is greater than the second number of nozzle structures.

13. The device of claim 8, wherein the plurality of nozzle structures further includes a first type of nozzle structures having a first size and a second type of nozzle structures having a second size different from the first size.

14. The device of claim 8, wherein:
the head further includes a first surface and a second surface opposite to the first surface; and
the plurality of electromagnetic strips are embedded in the head between the first surface and the second surface.

15. A device, comprising:
a head including a plurality of fluid openings;
a plurality of nozzle structures coupled to the head, each respective nozzle structure of the plurality of nozzle structures being in fluid communication with a corresponding fluid opening of the plurality of fluid openings, each respective nozzle structure of the plurality of nozzle structures being removable and replaceable relative to the head, the plurality of nozzle structures including a first type of nozzle structures having a first size and a second type of nozzle structures having a second size different from the first size, and each respective nozzle structure of the plurality of nozzle structures including:
a nozzle body having a first end and a second end opposite to the first end;
a fluid channel extending through the nozzle body from the first end to the second end; and
a flowrate monitoring structure embedded within the nozzle body, the flowrate monitoring structure comprising a Wheatstone bridge sensor configured to, in operation, measure a temperature of the respective nozzle structure to determine a flowrate through the fluid channel.

16. The device of claim 15, wherein the Wheatstone bridge sensor includes a temperature-sensitive wire embedded within the nozzle body.

17. The device of claim 15, wherein the Wheatstone bridge sensor is in electrical communication with a processor configured to, in operation, correlate a resistance change of the Wheatstone bridge sensor to the flowrate through the fluid channel.

18. The device of claim 15, wherein the plurality of fluid openings includes a first number of fluid openings, and wherein a total number of the first type of nozzle structures and the second type of nozzle structures is less than the first number of fluid openings.

19. The device of claim 15, wherein the head further includes a central portion and a peripheral portion, and at least one nozzle structure of the first type of nozzle structures is coupled to a fluid opening in the central portion and at least one nozzle structure of the second type of nozzle structures is coupled to a fluid opening in the peripheral portion.

20. The device of claim 15, wherein the first end of the nozzle body of each respective nozzle structure of the plurality of nozzle structures includes a tapered end configured to eject a fluid from the fluid channel.
